(19) United States
(12) Patent Application Publication
(10) Pub. No.: US 2013/0214102 A1
(43) Pub. Date: Aug. 22, 2013

(54) POWER RAIL ASSEMBLY

(71) Applicants: Wei-Chia HUANG, New Taipei City (TW); You-Gang WONG, New Taipei City (TW)

(72) Inventors: Wei-Chia HUANG, New Taipei City (TW); You-Gang WONG, New Taipei City (TW)

(73) Assignee: Wistron Corporation, New Taipei City (TW)

(21) Appl. No.: 13/564,351

(22) Filed: Aug. 1, 2012

(30) Foreign Application Priority Data
Feb. 16, 2012 (CN) 201210035672.7

(51) Int. Cl. H05K 7/00

(52) U.S. Cl. 248/125.2

(57) ABSTRACT

A power rail assembly includes a base, a bracket, a guiding member, a sliding seat, a screw member, a screw rod, and a driving motor. The base includes a top surface and a bottom surface. The bracket is disposed on the top surface vertically. The guiding member is disposed on the bracket and provides two guiding slots. The sliding seat includes a connection portion and two sliding portions. The two sliding portions protrude outwardly on the connection portion and embed into the two guiding slots respectively, so that the sliding set is movably disposed on the guiding member. The screw member is fixed on the connection portion and provides a screwing trough. The screw rod is disposed in an accommodating portion of the bracket and passes through the screwing trough, so that the screw member is engaged with the screw rod. The driving motor is fixed on the bracket.

### CROSS-REFERENCES TO RELATED APPLICATIONS

This non-provisional application claims priority under 35 U.S.C. §119(a) on Patent Application No. 201210035672.7 filed in China, P.R.C. on Feb. 16, 2012, the entire contents of which are hereby incorporated by reference.

### BACKGROUND

1. Technical Field

The disclosure relates to a rail assembly, and more particularly to a power rail assembly for lifting up and lowering a display.

2. Related Art

Generally a rail assembly includes a bracket and a sliding seat. The sliding seat is able to slide on the bracket along a sliding direction. On a cross-sectional plane perpendicular to the sliding direction of the sliding seat and the bracket, guiding structures compatible with each other are provided to prevent the sliding seat from sliding out of the bracket.

Rail assembles are frequently used to install displays to lift up and lower down displays. In order to fix a display at a certain height, a rail assembly includes inserting bolt structures to fasten the sliding seat and make the display fixed on the sliding seat without moving upward or downward. For example, US Patent Publication No. 2011/0176862 provides a locking structure to lock the sliding seat. However, such locking mechanism can only lock the display at a predetermined position, and cannot lock display at any desired height. In the meantime, during the process of adjusting the display's height, the user must manually hold the display. If the display is too heavy for the user to hold, adjusting the display would be very difficult to proceed. In US Patent Publication No. 2011/0176265, an elastic element is disposed between the sliding seat and the bracket so as to balance the weight of the display and reduce the loading of the user. However, the elasticity of the elastic element must match with the weight of the display. Higher or lower elasticity of the elastic component both cause difficult height adjustments for the display. Therefore, if the weight of the display changes, the elastic element must be redesigned as well, resulting in a poor universality for the rail assembly disclosed in US Patent Publication No. 2011/0176265.

### SUMMARY

When the slide assembly in the conventional technology is applied to lift and lower the display, the height of the display is not adjustable slightly. The display may only be adjusted at a predetermined height, and the weight of the display also results in inconvenience to the user.

In an embodiment of the disclosure, a provided power rail assembly includes a base, a bracket, a guiding member, a sliding seat, a screw member, a screw rod and a driving motor. The base includes a top surface and a bottom surface. The bracket is disposed vertically on the top surface and has an accommodating portion. The guiding member is disposed on the bracket and provides two guiding slots facing each other. The sliding seat includes a connection portion and two sliding portions; wherein the two sliding portions protrude outwardly on the connection portion and embed into the two guiding slots respectively, so that the sliding seat is movably disposed on the guiding member. The screw member is fixed on the connection portion and provides a screwing trough. The screw rod is disposed in the accommodating portion of the bracket; the screw rod passes through the screwing trough so that the screw member is engaged with the screw rod. The driving motor is fixed on the bracket and includes an output shaft connected to the screw rod, so as to rotate the screw rod and drive the sliding seat to slide between a first position and a second position.

By using the driving motor to drive the sliding seat, the display is driven to be lifted up and lowered; the height of the display is also adjustable slightly. When the driving motor stops rotating, the stopped screw rod is able to hold the display and prevent from lowering. Even though the weight of the display is greatly increased, the same screw rod is still able to hold the display with increase weights, without the need of considering how to prevent the display from lowering sinking as a result of gravity.

### BRIEF DESCRIPTION OF THE DRAWINGS

The disclosure will become more fully understood from the detailed description given herein below for illustration only, and thus not limitative of the present invention, wherein:

FIG. 1 is an explanatory exploded view of a power rail assembly according to an embodiment of the disclosure;

FIG. 2 and FIG. 3 are perspective views of a power rail assembly with different view angles according to the embodiments of the disclosure;

FIG. 4 is an exploded view of partial components of a power rail assembly according to another embodiment of the disclosure;

FIG. 5 and FIG. 6 are perspective views of partial components of a power rail assembly according to the embodiments of the disclosure; and

FIG. 7 is an explanatory exploded view of partial components of a power rail assembly according to another embodiment of the disclosure.

### DETAILED DESCRIPTION

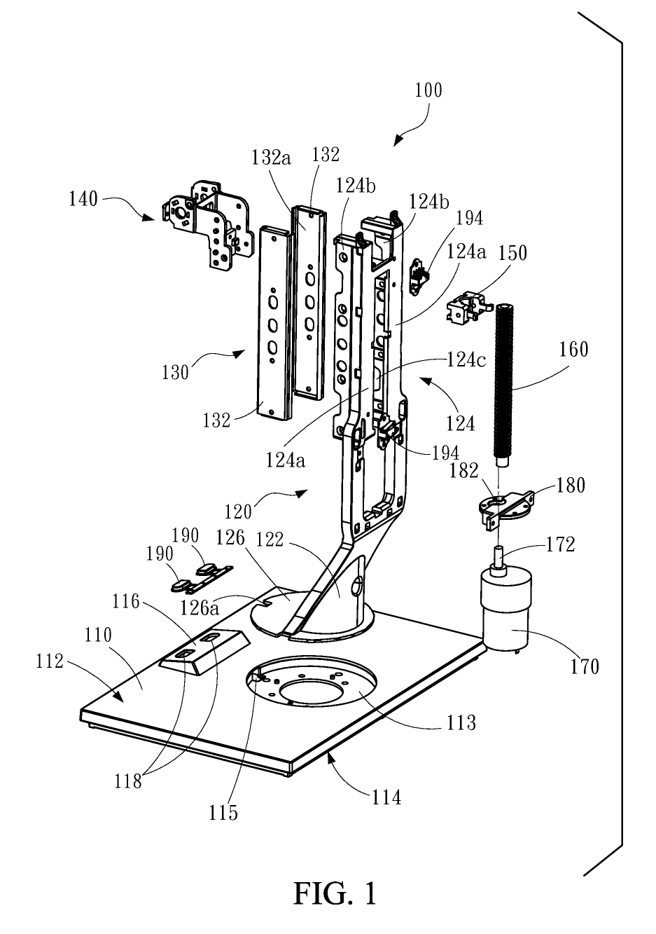

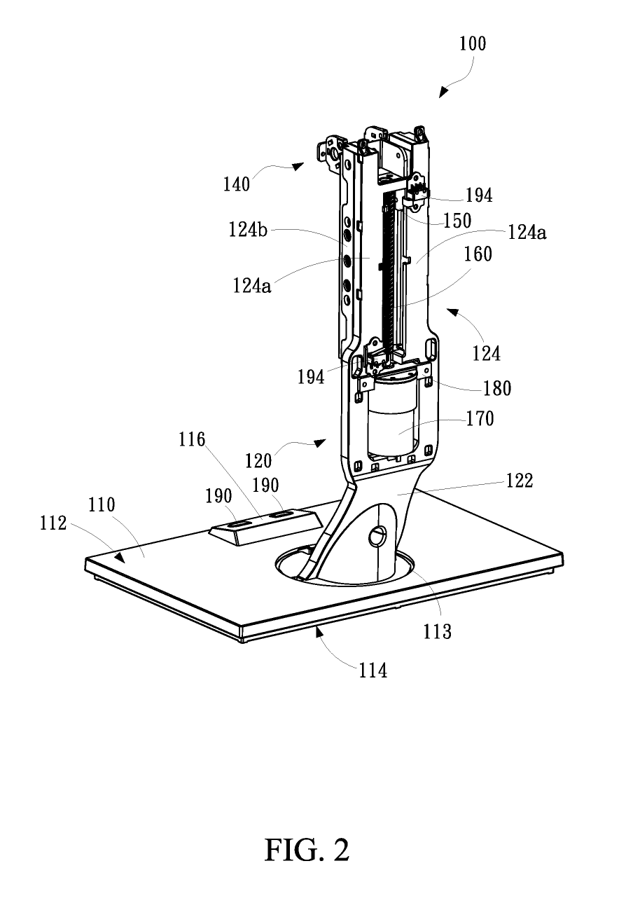

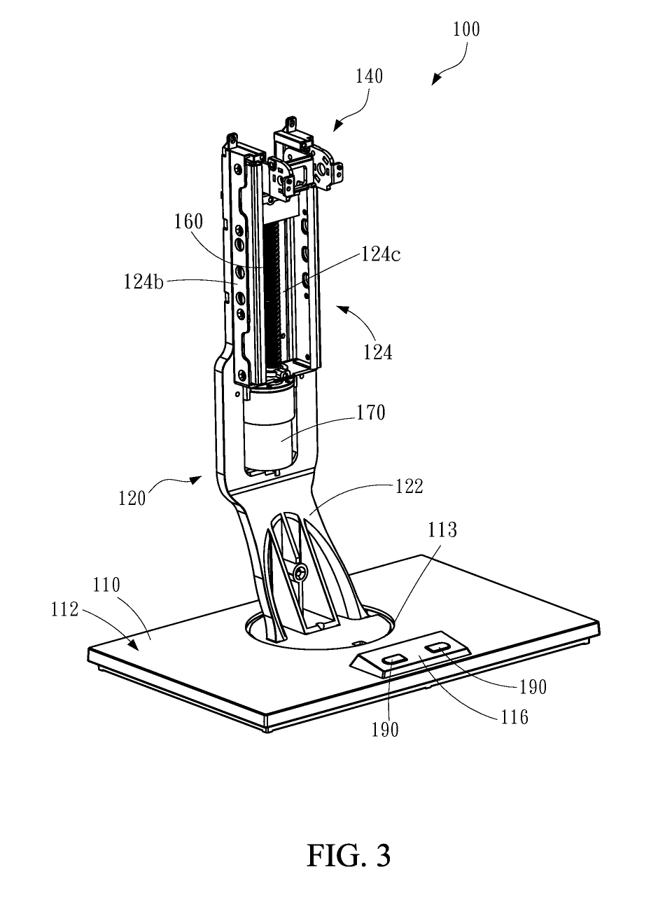

Please refer to FIG. 1, FIG. 2 and FIG. 3, which illustrate a power rail assembly 100 according to an embodiment of the disclosure; the power rail assembly is used for combining with a display to lift up and lower down the display. The power rail assembly 100 includes a base 110, a bracket 120, a guiding member 130, a sliding seat 140, a screw member 150, a screw rod 160 and a driving motor 170.

As shown in FIG. 1, FIG. 2 and FIG. 3, the base 110 includes a top surface 112 and a bottom surface 114. The bracket 120 is disposed on the top surface 112 of the base 110. The bracket 120 includes a fixing portion 122 and an accommodating portion 124. The fixing portion 122 is fixed on the top surface 112 of the base 110, so that the bracket 120 is disposed vertically on the top surface 112 of the base 110 and the accommodating portion 124 is extended away from the top surface 112. The accommodating portion 124 includes two pillars 124a spaced with an interval distance in between. The accommodating portion 124 further includes two side boards 124b that are extended from the two pillars 124a respectively and disposed in parallel with each other, so that an accommodating space 124c is formed between the two side boards 124b.

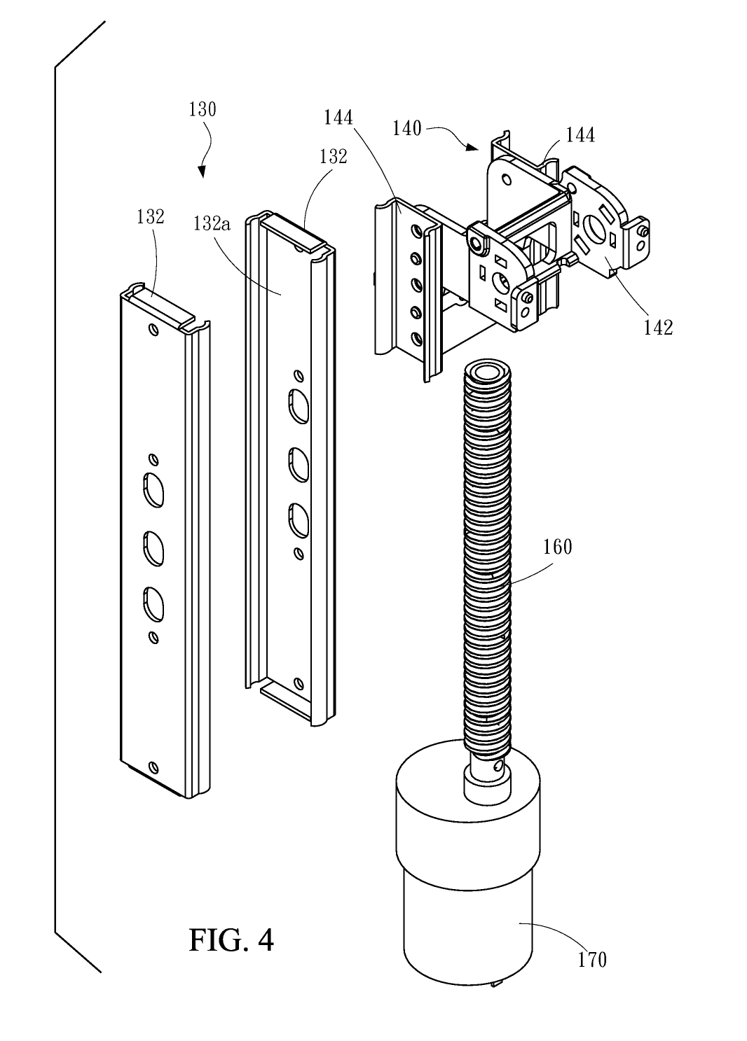

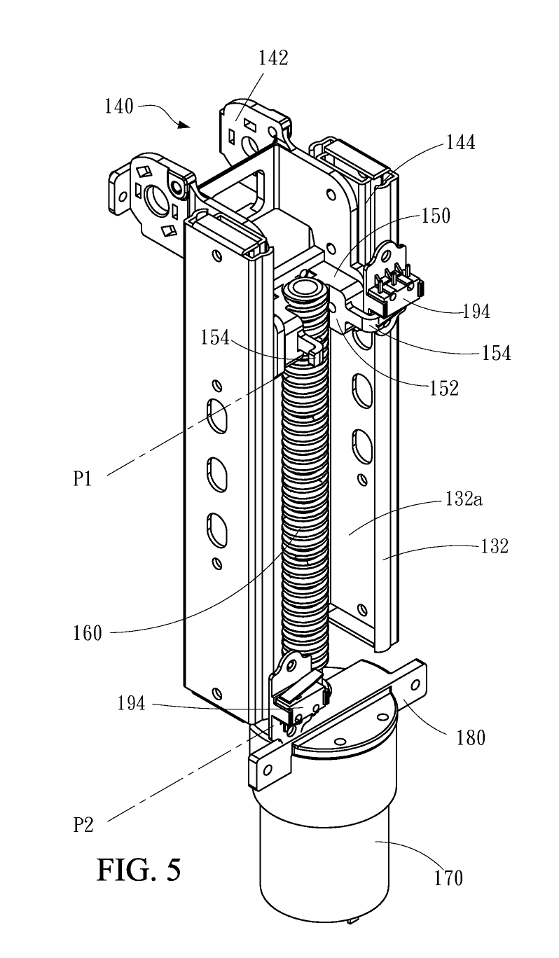

As shown in FIG. 1, FIG. 2, FIG. 3, FIG. 4 and FIG. 5, the guiding member 130 is fixed on the accommodating portion 124 of the bracket 120. The guiding member 130 provides two guiding slots 132a facing each other. The guiding member 130 includes two rails 132 respectively fixed on the two side boards 124b of the bracket 120, so that the two rails 132 are spaced with an interval distance in between and disposed in parallel with each other. Each of the rails 132 respectively provides a guiding slot 132a.

As shown in FIG. 1, FIG. 2, FIG. 3, FIG. 4 and FIG. 5, the sliding seat 140 includes a connection portion 142 and two sliding portions 144. The connection portion 142 is used to be fixed onto the rear side of the display. The two sliding portions 144 protrude outwardly on the connection portion 142 and embed into the two guiding slots 132a; wherein the two sliding portions 144 are rectangular and attached to two opposite sides of the connection portion 142 respectively. The width of each of the sliding portions 144 matches the width of each of the guiding slots 132a, so that the sliding seat 140 is movably disposed between the two rails 132 of the guiding member 130.

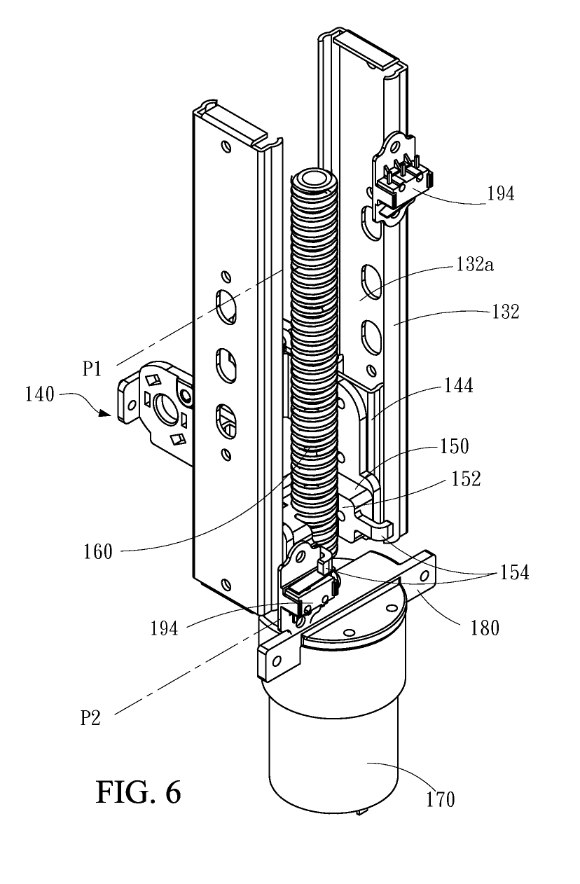

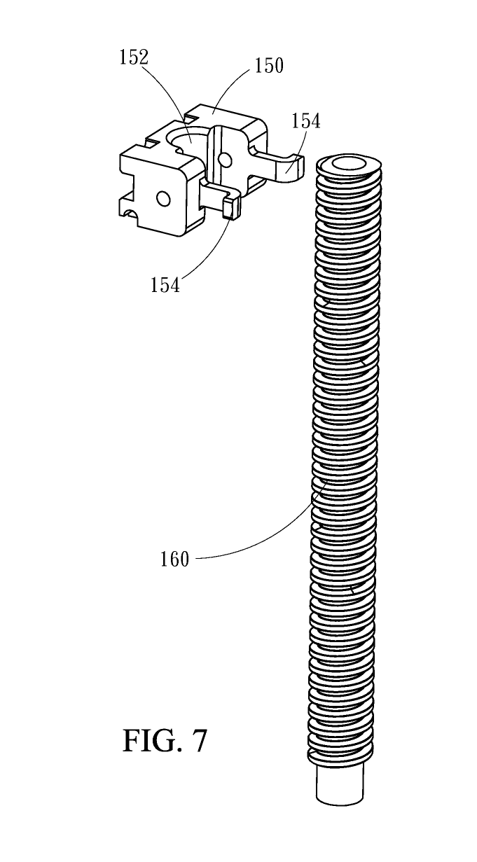

As shown in FIG. 5, FIG. 6 and FIG. 7, the screw member 150 is fixed on the sliding seat 140; wherein the screw member 150 is fixed on the connection portion 142, and the screw member 150 provides a screwing trough 152. The screw rod 160 is disposed in the accommodating portion 124 of the bracket 120, between the two rails 132. The screw rod 160 passes through the screwing trough 152, so that the screw member 150 is engaged with the screw rod 160. The rotating operation of the screw rod 160 is therefore able to be transferred into the linear driving for the screw member 150. The driving motor 170 is fixed on the bracket 120, and an output shaft 172 of the driving motor 170 is connected to the screw rod 160, so as to rotate the screw rod 160 and drive the sliding seat 140 to slide between a first position P1 and a second position P2.

As shown in FIG. 1, FIG. 2, FIG. 5 and FIG. 6, in an embodiment, the power rail assembly 100 further includes a motor mount 180 fixed on the bracket 120; wherein the motor mount 180 is fixed between the two pillars 124a, and the motor mount 180 further includes a through hole 182. The driving motor 170 is fixed to the motor mount 180, and the output shaft 172 passes through the through hole 182 to connect with the screw rod 160.

As shown in FIG. 1, FIG. 2 and FIG. 3, a button base 116 is disposed convexly on the top surface 112 of the base 110. The button base 116 provides multiple button holes 118 thereon. The power rail assembly 100 further includes multiple buttons 190, respectively disposed on the base 110 and exposed through the button holes 118. These buttons 190 are used to be pressed and generate control signals, so as to control the forward rotation and reverse rotation of the driving motor 170 for lifting up and lowering the sliding seat 140. For example, the power rail assembly 100 includes two buttons 190, and the button base 116 includes two button holes 118; one of the two buttons 190 is used to control the forward rotation of the driving motor 170 for lifting up the sliding seat 140; the other button 190 is used to control the reverse rotation of the driving motor 170 for lowering the sliding seat 140.

As shown in FIG. 5 and FIG. 6, the sliding seat 140 is lifted up and lowered between the first position P1 and the second position P2; wherein the first position P1 is approximately corresponding to the end of the screw rod 160, and the second position P2 is approximately corresponding to the connecting position between the screw rod 160 and the output shaft 172 of the driving motor 170. The power rail assembly 100 further includes two limit switches 194 disposed on the bracket 120, and the limit switches 194 respectively corresponds to the first position P1 and the second position P2. The screw member 150 further includes at least a contact unit 154, used for contacting one of the two limit switches 194 at the first position P1 or the second position P2. When any of the two limit switches 194 is contacted by the contact unit 154, the contacted limit switch 194 generates a termination signal to terminate the rotation of the driving motor 170. Therefore, the driving motor 170 is only able to drive the sliding seat 140 to move between the first position P1 and the second position P2, which makes the screw member 150 remain engaged with the screw rod 160.

In an embodiment, the screw member 150 includes two contact units 154 that respectively extend out of the accommodating portion 124 and respectively correspond to one of the pillars 124a; the two limit switches 194 are respectively disposed on the two pillars 124a, so that each of the contact units 154 is able to contact one of the limit switches 194.

As shown in FIG. 1, FIG. 2 and FIG. 3, in an embodiment, the base 110 further includes a positioning groove 113, and a positioning block 115 is disposed convexly on an inner wall of the positioning groove 113. The fixing portion 122 of the bracket 120 further includes a positioning plate 126, compatible with the shape of the positioning groove 113. The positioning plate 126 is used to fix in the positioning groove 113; the positioning plate 126 includes a positioning notch 126a for the positioning block 115 to embed therein. The positioning groove 113 and the positioning plate 126 are used to correctly fix the bracket 120 into a designated position on the top surface 112; the positioning notch 126a and the positioning block 115 are used to align the sliding seat 140 of the power rail assembly 100 toward a right direction, which also makes the display aligned toward a right direction.

Please refer to FIG. 5 and FIG. 6. The driving motor 170 is used to drive the sliding seat 140 to move between the first position P1 and the second position P2, and the sliding seat 140 is attached to the display. Therefore, by using the driving motor 170 to drive the sliding seat 140, the display is driven to be lifted up and lowered; the height of the display is also adjustable slightly. Since the screw rod 160 has the function of enlarging the driving force of the driving motor 170, the driving motor 170 is able to drive heavier displays with higher weights. Meanwhile, when the driving motor 170 stops rotating, the stopped screw rod 160 is able to hold the display and prevent from lowering. Even though the weight of the display is greatly increased, the same screw rod 160 is still able to hold the display with increase weights and prevent from lowering. Therefore, during the design process of the power rail assembly 100, instead of considering how to prevent the display from lowering sinking as a result of gravity, what really must be considered is if the driving force of the driving motor 170 is enough to lift up the display.

While the disclosure has been described by the way of example and in terms of the preferred embodiments, it is to be understood that the invention need not be limited to the disclosed embodiments. On the contrary, it is intended to cover various modifications and similar arrangements included within the spirit and scope of the appended claims, the scope of which should be accorded the broadest interpretation so as to encompass all such modifications and similar structures.

What is claimed is:

1. A power rail assembly, comprising:
a base, comprising a top surface and a bottom surface;
a bracket, comprising an accommodating portion, disposed vertically on the top surface;
a guiding member, disposed on the bracket, providing two guiding slots facing each other;
a sliding seat, comprising a connection portion and two sliding portions, wherein the two sliding portions protrude outwardly on the connection portion and embed into the two guiding slots respectively, so that the sliding seat is movably disposed on the guiding member;
a screw member, fixed on the connection portion, the screw member providing a screwing trough;
a screw rod, disposed in the accommodating portion of the bracket, the screw rod passing through the screwing trough so that the screw member is engaged with the screw rod; and
a driving motor, fixed on the bracket, the driving motor comprising an output shaft connected to the screw rod, so as to rotate the screw rod and drive the sliding seat to slide between a first position and a second position.

2. The power rail assembly according to claim 1, wherein the bracket comprises:
a fixing portion, fixed on the top surface of the base;
wherein the accommodating portion comprises two side boards disposed in parallel with each other, the guiding member comprises two rails respectively fixed on the side boards, and each of the rails provides one of the guiding slots.

3. The power rail assembly according to claim 2, wherein the accommodating portion comprises two pillars spaced with an interval distance in between, and the two side boards are extended from the two pillars respectively.

4. The power rail assembly according to claim 3, wherein the two sliding portions are rectangular and attached to two opposite sides of the connection portion respectively, and the width of each of the sliding portions matches the width of each of the guiding slots.

5. The power rail assembly according to claim 3, wherein the screw rod is disposed between the two rails.

6. The power rail assembly according to claim 5 further comprising a motor mount fixed between the two pillars, and the motor mount further comprising a through hole; wherein the driving motor is fixed to the motor mount, and the output shaft passes through the through hole to connect with the screw rod.

7. The power rail assembly according to claim 3 further comprising two limit switches disposed on the bracket, each of the limit switches respectively corresponding to the first position and the second position, and being used to generate a termination signal when contacted, so as to terminate the rotation of the driving motor.

8. The power rail assembly according to claim 7, wherein the screw member comprises at least a contact unit, used to contact one of the two limit switches at the first position or the second position.

9. The power rail assembly according to claim 8, wherein the screw member comprises two contact units, the contact units being respectively extended out of the accommodating portion and respectively corresponding to a pillar, and the two limit switches are respectively disposed on the two pillars, so that each of the contact units is able to contact one of the limit switches.

10. The power rail assembly according to claim 1 further comprising a plurality of buttons, the buttons being disposed on the base and used to generate control signals when pressed, so as to control forward rotation and reverse rotation of the driving motor.

11. The power rail assembly according to claim 7, wherein a button base is disposed convexly on the top surface of the base, and the button base comprises a plurality of button holes; the buttons being disposed on the base and respectively exposed through the button holes.

12. The power rail assembly according to claim 2, wherein the base further comprises a positioning groove thereon, and the fixing portion of the bracket further comprises a positioning plate used for fixing in the positioning groove.

13. The power rail assembly according to claim 12, wherein a positioning block is disposed convexly on an inner wall of the positioning groove, and the positioning plate comprises a positioning notch for the positioning block to embed therein.
